(19) United States
(12) Patent Application Publication
(10) Pub. No.: US 2024/0221811 A1
(43) Pub. Date: Jul. 4, 2024

(54) ENERGY-EFFICIENT CRYOGENIC-IN-MEMORY-COMPUTING (CIMC) ACCELERATOR

(71) Applicant: SHANGHAITECH UNIVERSITY, Shanghai (CN)

(72) Inventors: Yuhao SHU, Shanghai (CN); Hongtu ZHANG, Shanghai (CN); Yajun HA, Shanghai (CN)

(73) Assignee: SHANGHAITECH UNIVERSITY, Shanghai (CN)

(21) Appl. No.: 18/229,698

(22) Filed: Aug. 3, 2023

Related U.S. Application Data
(63) Continuation of application No. PCT/CN2023/083264, filed on Mar. 23, 2023.

(30) Foreign Application Priority Data
Dec. 28, 2022 (CN) 202211694748.7

(51) Int. Cl. G11C 11/405; G06F 17/15; G11C 11/4091; G11C 11/4096; H03K 19/20

(52) U.S. Cl. CPC G11C 11/405; G06F 17/153; G11C 11/4091; G11C 11/4096; H03K 19/20

(57) ABSTRACT

An energy-efficient cryogenic-in-memory-computing (CIMC) accelerator includes cryogenic 3T (C3T) macros. Each of the C3T macros comprises a C3T array containing M rows×N columns of bitcells. An input signal is converted into a timing sequence signal of a corresponding pulse width by using a digital timing sequence converter array. A C3T bitcell of a corresponding row in the C3T macro is controlled to perform charging and discharging on a read bit line (RBL) of a corresponding column. A voltage on the RBL of the corresponding column is sampled by a sense amplifier configured in each C3T macro to obtain a final result. With adaptive reference voltage configuration and storage on the chip, this design can achieve fast and low-power boolean/convolutional computing.

### CROSS REFERENCE TO THE RELATED APPLICATIONS

This application is the Continuation Application of International Application No. PCT/CN2023/083264, filed on Mar. 23, 2023, which is based upon and claims priority to Chinese Patent Application No. 202211694748.7, filed on Dec. 28, 2022, the entire contents of which are incorporated herein by reference.

### TECHNICAL FIELD

The present disclosure relates to a design of an energy-efficient cryogenic-in-memory-computing (CIMC) accelerator.

### BACKGROUND

As the development of the integrated circuit (IC) industry following Moore's law reaches a bottleneck, more research work is looking for an alternative technology and architecture to further improve performance of the IC. The complementary metal-oxide-semiconductor transistor (CMOS) in a cryogenic environment^{[1]-[2]} presents an almost ideal performance, which further promotes the development of cryogenic applications, and cryogenic computing has also received considerable attention in the past few years. However, cryogenic computing cannot eliminate the current performance bottleneck, such as the memory wall. In order to resolve the above problem, a cryogenic computing architecture based on in-memory-computing (IMC) is a very promising solution. The cryogenic computing architecture is suitable for operating at the cryogenic temperature, reduces a cooling cost through extremely high energy efficiency, and achieves energy-efficient computing and storage capabilities with a relatively small adjustment to the architecture.

However, existing IMC research^{[3]-17]} still has a plurality of challenges in improving energy efficiency at the cryogenic temperature. Specifically, the existing cryogenic enhanced dynamic random access memory (eDRAM) is not optimal for achieving a reliable write operation, and its bitcell topology needs to be redesigned for the cryogenic temperature. The requirement for different computing operations in different scenarios of cryogenic computing needs to be met through energy-efficient Boolean logic computing and energy-efficient convolutional operations.

### CITED REFERENCES

[1] D. Min, I. Byun, G.-H. Lee, S. Na, and J. Kim, “Cryocache: A fast, large, and cost-effective cache architecture for cryogenic computing,” in Proceedings of the Twenty-Fifth International Conference on Architectural Support for Programming Languages and Operating Systems, ser. ASPLOS '20. New York, NY, USA: Association for Computing Machinery, March 2020, p. 449-464.
[2] I. Byun, D. Min, G.-h. Lee, S. Na, and J. Kim, “Cryocore: A fast and dense processor architecture for cryogenic computing” in 2020 ACM/IEEE 47th Annual International Symposium on Computer Architecture (ISCA), May 2020, pp. 335-348.
[3] Chen, Zhengyu, Xi Chen, and Jie Gu. “15.3 A 65 nm 3T Dynamic Analog RAM-Based Computing-in-Memory Macro and CNN Accelerator with Retention Enhancement, Adaptive Analog Sparsity and 44TOPS/W System Energy Efficiency.” 2021 IEEE International Solid-State Circuits Conference (ISSCC). Vol. 64. IEEE, 2021.
[4] Xie, Shanshan, et al. “16.2 eDRAM-CIM: compute-in-memory design with reconfigurable embedded-dynamic-memory array realizing adaptive data converters and charge-domain computing.” 2021 IEEE International Solid-State Circuits Conference (ISSCC). Vol. 64. IEEE, 2021.
[5] Dong, Qing, et al. “15.3 A 351TOPS/W and 372.4 GOPS compute-in-memory SRAM macro in 7 nm FinFET CMOS for machine-learning applications.” 2020 IEEE International Solid-State Circuits Conference-(ISSCC). IEEE, 2020.
[6] Fujiwara, Hidehiro, et al. “A 5-nm 254-TOPS/W 221-TOPS/mm 2 Fully-Digital Computing-in-Memory Macro Supporting Wide-Range Dynamic-Voltage-Frequency Scaling and Simultaneous MAC and Write Operations.” 2022 IEEE International Solid-State Circuits Conference (ISSCC). Vol. 65. IEEE, 2022.
[7] Si, Xin, et al. “24.5 A twin-8T SRAM computation-in-memory macro for multiple-bit CNN-based machine learning.” 2019 IEEE International Solid-State Circuits Conference-(ISSCC). IEEE, 2019.

### SUMMARY

The present disclosure is intended to resolve following technical problems: An existing cryogenic eDRAM is not optimal for achieving a reliable write operation, and its bitcell topology needs to be redesigned at a cryogenic temperature. Requirements for different computing operations in different scenarios of cryogenic computing need to be met through energy-efficient Boolean logic computing and energy-efficient convolutional operations.

In order to resolve the above technical problems, the technical solutions of the present disclosure provide an energy-efficient CIMC accelerator, including cryogenic 3T (C3T) macros, where each of the C3T macros includes a C3T array containing M rows×N columns of bitcells, an input signal is converted into a timing sequence signal of a corresponding pulse width by using a digital timing sequence converter (DTC) array, and controls a C3T bitcell of a corresponding row in the C3T macro to perform charging and discharging on a read bit line (RBL) of a corresponding column; and a voltage on the RBL of the corresponding column is sampled by a sense amplifier configured in each C3T macro to obtain a final result, where
during a non-convolutional operation, the RBL of the corresponding column is directly connected to the sense amplifier; and
in a convolutional operation mode, on or off of a switch is controlled: convolutional capacitors of a same size are first connected to an RBL of each column; after the convolutional capacitor is charged and discharged, RBLs of adjacent two columns are connected together to achieve charge redistribution between different columns; and finally, the RBL is disconnected from the sense amplifier, and charges of different magnitudes on different columns are sampled by the sense amplifier to generate the final output result.

Preferably, the C3T bitcell includes a transmission gate write port constituted by a pair of complementary metal-oxide-semiconductor transistor (CMOS) structures that are complementary to each other and a read port constituted by a single-transistor N-channel metal oxide semiconductor (NMOS); for a write operation, stored data is written into a storage node (SN) through a write bit line (WBL) and the transmission gate write port controlled by a pair of a write word line (WWL) and a WWLB; and for a read operation, different charging and discharging behaviors of the RBL are achieved by controlling a pulse width length of a read signal RWL.

Preferably, two input terminals of the sense amplifier each are provided with one transmission gate switch and one storage capacitor, and a sampling transistor and the transmission gate switch of the input terminal on each side of the sense amplifier constitute an SN for storing a sampled voltage V_{REF}; in a sampling process, the voltage on the RBL is latched in the V_{REF} by the transmission gate switch on one side of the sense amplifier; and after the sampled voltage is latched, the transmission gate switch on the one side of the sense amplifier is in a disconnected state to ensure that the sampled voltage is not affected by a voltage change on the RBL and is always stored in the V_{REF}, and an actual computing result is sampled by the transmission gate switch on the other side of the sense amplifier and compared with the stored V_{REF} to generate the final output result.

Preferably, Boolean computing is implemented according to following steps:
storing reference data of a corresponding sampled voltage into the C3T macro;
enabling a plurality of rows of word lines of the C3T macro to generate a corresponding column-oriented result;
connecting RBLs of adjacent columns to obtain a charge redistribution result; and
storing the charge redistribution result to the sense amplifier of a corresponding column, and latching the charge redistribution result in the V_{REF}, where for any input NAND or NOR operation, a reference voltage for determining the result is generated and stored to the sense amplifier to achieve a corresponding computing operation.

Preferably, a single 4-bit flash analog-to-digital converter (ADC) is formed by 15 sense amplifiers in the C3T macro, and adaptive 15 V_{REF} S are generated before the convolutional operation.

Compared with the prior art, the present disclosure has following innovative points:
1) Design of a C3T bitcell with long retention time (RT): The present disclosure designs a C3T bitcell based on an eDRAM, which can significantly improve RT without any word line voltage increase scheme, and achieve full-swing data transmission during a write operation.
2) Design of a cryogenic adaptive reconfigurable sense amplifier (ARSA): The present disclosure designs a cryogenic on-chip ARSA, and accurate on-chip Boolean logic computing can be achieved by configuring a reference voltage of the ARSA.
3) Design of a cryogenic optimized flash ADC: The present disclosure uses the designed ARSA to adaptively generate 15 reference voltages of the ARSA on a chip and reconstruct the cryogenic optimized flash ADC into a 4-bit flash ADC. With adaptive reference voltage configuration and storage on the chip, this design can achieve fast and low-power convolutional computing.

A chip test result shows that compared with 3.7 us data RT at 300K, the retention time achieved by the C3T design provided in the present disclosure is increased to 9.1s at 4.2K. A 144 Kb CIMC of the present disclosure achieves an average energy efficiency of 603.1 TOPS/W and an average computational density of 284 TOPS/mm², which are respectively 2.37 times and 1.29 times higher than those achieved by most advanced 5 nm technology research work [6].

### BRIEF DESCRIPTION OF THE DRAWINGS

FIG. 1 shows a design of a CIMC architecture (a C3T array, an ARSA, and a cryogenic flash ADC);

FIG. 2 illustrates a design of a C3T bitcell and control signals for different operating modes;

FIG. 3 illustrates a design of an ARSA;

FIG. 4 is a schematic diagram of implementing Boolean logic based on an ARSA;

FIGS. 5A-5D illustrate a flash ADC design based on an ARSA, including adaptive V_{REF} generation, a convolution process, and a measurement result;

FIGS. 6A-6E illustrate RT, accuracy, energy efficiency, and power consumption measurement results of CIMC; and

FIG. 7 illustrates a summary of a design of the present disclosure and a comparison result with state-of-the-art research work.

### DETAILED DESCRIPTION OF THE EMBODIMENTS

The present disclosure will be further described below with reference to specific embodiments. It should be understood that these embodiments are only intended to describe the present disclosure, rather than to limit the scope of the present disclosure. In addition, it should be understood that various changes and modifications may be made on the present disclosure by those skilled in the art after reading the content of the present disclosure, and these equivalent forms also fall within the scope defined by the appended claims of the present disclosure.

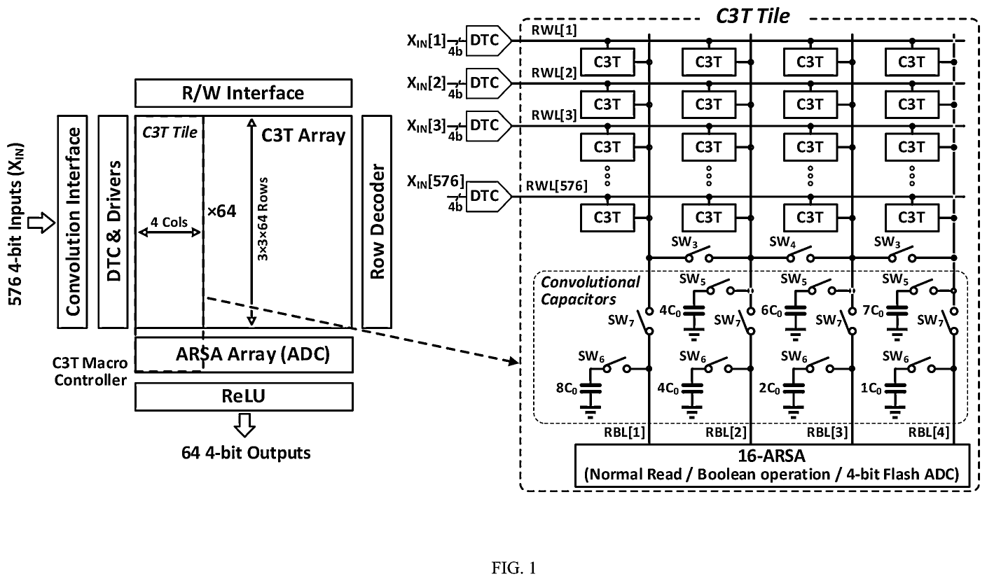

As shown in FIG. 1, a 144 Kb CIMC architecture disclosed in the embodiments includes a DTC array, 64 C3T tiles, an ARSA array, a ReLU, a read/write interface (R/W interface), and other peripheral circuits that support conventional memory operations. An input signal is converted into a timing sequence signal of a corresponding pulse width by the DTC array, and controls a C3T bitcell of a corresponding row to perform charging and discharging on an RBL. A voltage on the RBL is sampled by a sense amplifier configured in each C3T tile to obtain a final result. During a non-convolutional operation, in order to reduce a charging energy consumption of a large-load capacitor on the RBL, the present disclosure disconnects a convolutional capacitor from the RBL, that is, SW₃ to SW₆ in a bottom right corner of FIG. 1 will be in a disconnected state, and switch SW₇ will be in a connected state to achieve a connection between the RBL and the sense amplifier. In a convolutional operation mode, the switches SW₅ to SW₇ are turned off to connect a convolutional capacitor with a size of 8C₀ to an RBL of each column. After the convolutional capacitor is charged and discharged, the switches SW₃ and SW₄ are turned off to achieve charge redistribution between different columns. Finally, the switch SW₇ is disconnected. In this case, only charges on capacitors with sizes of 8C₀, 4C₀, 2C₀, and C₀ in different columns are sampled by the sense amplifier to generate the final output result.

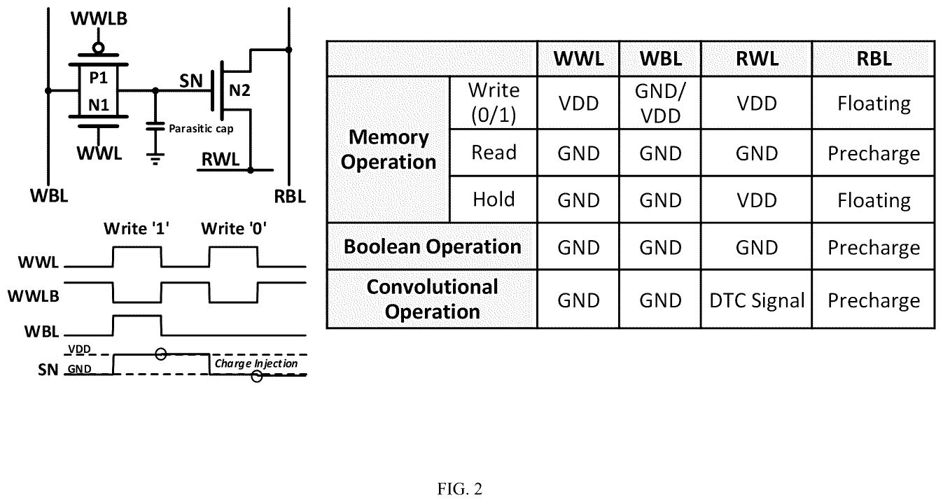

With reference to FIG. 2, although a single-type write access transistor (N-type or P-type) used in a room-temperature eDRAM design can effectively reduce data leakage of an SN, a full-swing data write problem caused by a threshold voltage drop cannot be avoided. This situation is more severe at a cryogenic temperature. A power consumption and a device life impact generated by a solution that uses a word line voltage boosting technology at the cryogenic temperature also make this structure unsuitable for a cryogenic design. In addition, a charge injection effect from a WWL to the SN further attenuates data storage after a write operation. To resolve this problem, the present disclosure designs a C3T gain unit, which includes a write port constituted by a pair of transmission gates (P1 and N1) and a read port constituted by a single-transistor NMOS (N2). Stored data is written into the SN in a bitcell through the WBL and a transmission gate write port controlled by a pair of the WWL and a WWLB. For a read operation, based on the design of the present disclosure, the bitcell supports Boolean and convolutional operations in addition to conventional storage operations. Main implementation of the Boolean and convolutional operations is to achieve different charging and discharging behaviors of the RBL by controlling a pulse width length of read signal RWL. As shown in a timing chart in a bottom left corner of FIG. 2, because the transmission gate write port is constituted by a pair of CMOS structures that are complementary to each other, any stored data can be stored to the SN through this structure, and this structure can also eliminate an impact of the charge injection effect on the stored data.

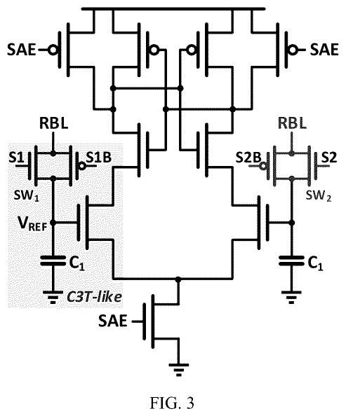

As shown in FIG. 3, unlike a conventional sense amplifier, an ARSA disclosed in the embodiments adds one transmission gate switch and one storage capacitor C1 to two input terminals of the conventional sense amplifier respectively. In this way, a sampling transistor and the switch on each input terminal form a stable SN that can be configured to store sampled voltage V_{REF}. Such a structure of storing the sampled voltage in this way is referred to as C3T-like because it is similar to the designed C3T bitcell in the present disclosure. A complete operation process of the ARSA is as follows: Firstly, in a sampling process, the voltage on the RBL is latched in the V_{REF} through switch SW formed by transmission gate S1/S1B. After the sampled voltage is latched, the SW₁ is in the disconnected state to ensure that the sampled voltage is not affected by a voltage change on the RBL and is always stored in the V_{REF}. An actual computing result will is sampled by switch SW₂ formed by S2/S2B and compared with the stored V_{REF} to generate the final output result.

As shown in FIG. 4, in order to achieve Boolean computing, it is necessary to first store reference data (REF Data) of a corresponding sampled voltage (REF Data) to a memory array, and then a plurality of rows of word lines are enabled to generate a corresponding column-oriented result. After that, adjacent columns need to be connected through switch SW₃ to obtain a charge redistribution result. Finally, the charge redistribution result is stored to the ARSA of a corresponding column, and latched in the V_{REF}. For any input NAND or NOR operation, only a reference voltage for determining the result needs to be generated according to the above process and stored to the ARSA to achieve a corresponding computing operation. After the reference data is stored, gating of a plurality of rows is controlled by the read signal RWL, and a result is generated on the column. Then, the adjacent columns are connected together and share the result through the column switch SW₃. After that, the result is stored to the ARSA to obtain first reference voltage V_{REF} [1]. To generate V_{REF} [2] or another reference voltage, it is only required to simply gate a corresponding row and then repeat the above operations.

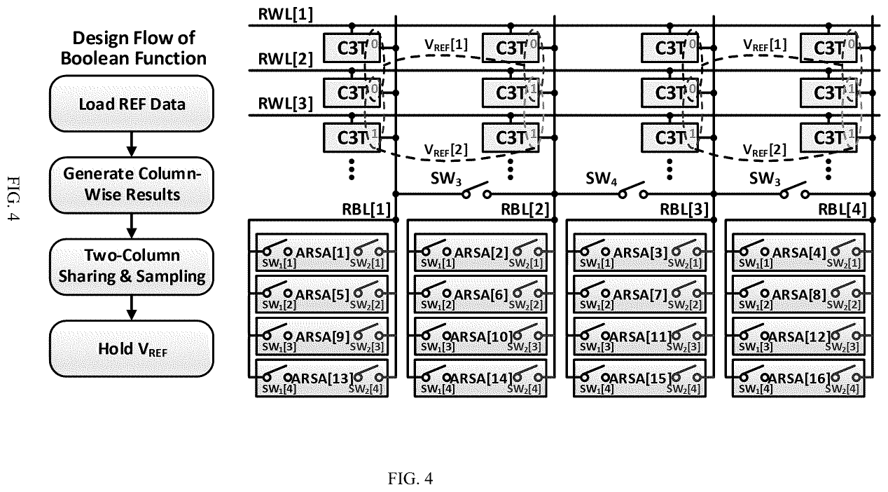

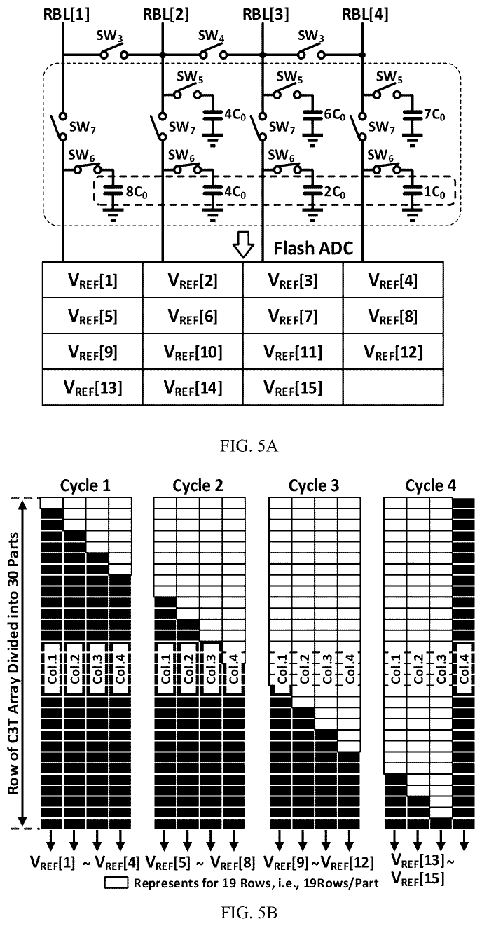

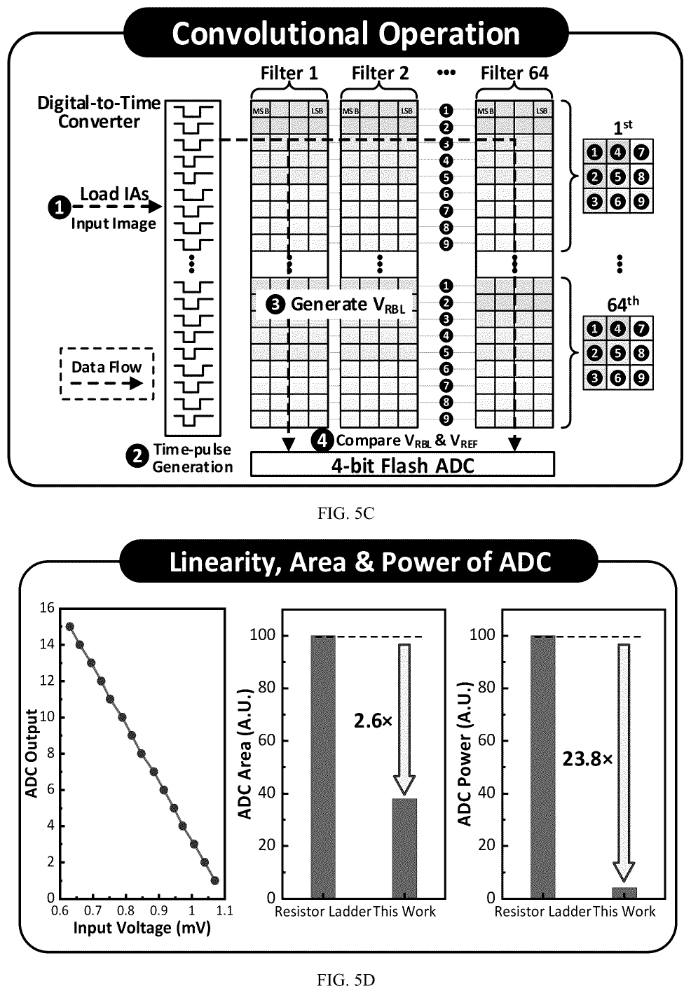

FIG. 5A shows a structural diagram of reconstructing 15 V_{REF} S into a 4-bit flash ADC, which also shows a charge redistribution process of a 4-bit convolutional operation. A single 4-bit flash ADC is formed by 15 ARSAs in the C3T tile, and adaptive 15 V_{REF} S are generated before the convolutional operation. FIG. 5B shows a pre-sampling process of the adaptive 15 V_{REF} S. In a first cycle (cycle 1), RBL [1:4] performs discharging to achieve different voltage levels based on a quantity of “1s” stored in each column. The C3T array is divided into 30 parts, and each part contains 19 rows (an array size is 576 rows×256 columns, and 576 rows/30˜19 rows). For example, in order to obtain the V_{REF} [1] and the V_{REF} [2], 19×1 ‘1s’ are stored to a first column of the C3T tile, and 19×3 ‘1s’ are written into a second column. In this case, voltages of RBL[1] and RBL[2] decrease with voltage drops of (V_{H}−V_{L})/30 and 3 (V_{H}−V_{L})/30 respectively (the V_{H} and the V_{L} are maximum and minimum values of convolutional computing).

A convolutional operation process of the CIMC and a corresponding data mapping rule are shown in FIG. 5C. An input activation value (IA) is processed by a DTC to generate a corresponding time pulse signal. After all rows are enabled, the convolutional computing can be performed through charge sharing, and voltage V_{RBL} can be generated on the RBL. The V_{RBL} IS compared with the pre-sampled V_{REF} to obtain the final result. A measurement result of the 4-bit flash ADC is shown in FIG. 5D. Linearity of the convolutional computing is verified by changing the quantity of ‘1s’ stored in the column. The result indicates that the structure has a good linear ADC output. Compared with a trapezoidal-resistance ADC, the 4-bit flash ADC formed by the ARSAs reduces its area and power consumption by 2.6 and 23.8 times respectively at 4.2 K.

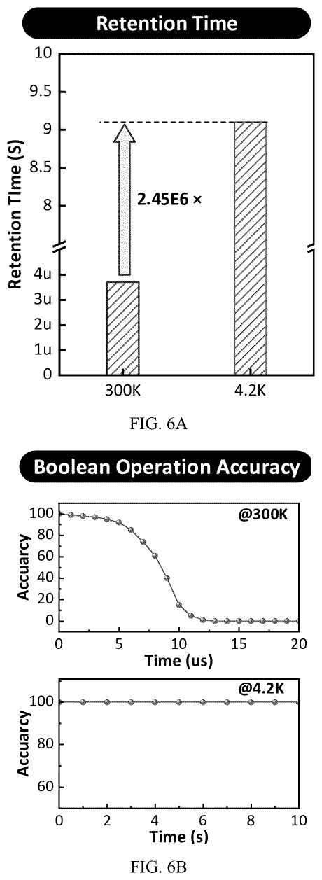

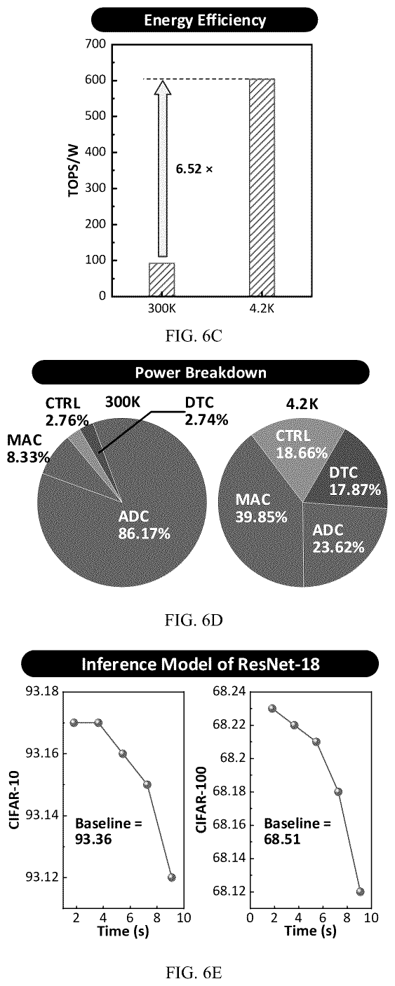

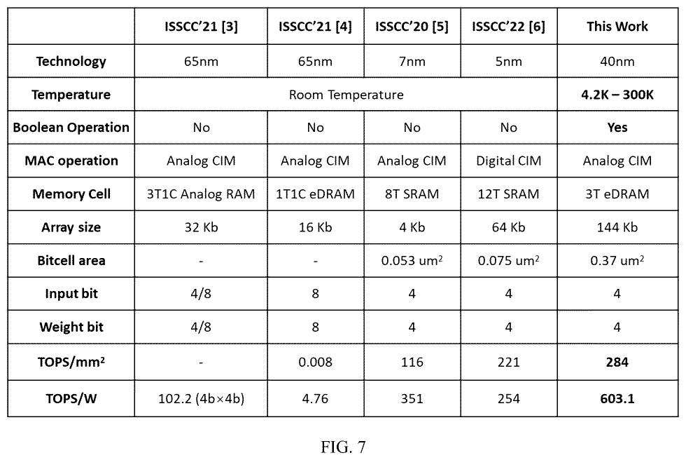

FIGS. 6A-6E show a measurement result of a 144 Kb C3T macro chip manufactured in a 40 nm process. For RT, a 0.1 V data voltage change is used as a critical condition for triggering a data refresh operation. Compared with 3.7 us RT at 300K, average RT of the C3T macro (in other words, “C3T tile”) of the present disclosure is 9.1 s at 4.2K. For Boolean computing, this C3T macro can achieve precise computing over a long period of time without a need to refresh the reference voltage of the ARSA. For the convolutional computing, the present disclosure achieves an energy efficiency of 603.1 TOPS/W, which is 6.52 times a test result at 300K. In addition, the present disclosure also achieves a computational density of up to 284 TOPS/mm². A power consumption decomposition diagram of a chip shows that a power consumption overhead of the flash ADC reaches 86.17% at 300K, while the present disclosure can reduce the power consumption overhead to 23.62% at 4.2K. For a ResNet-18 model, the C3T macro at 4.2K achieves a highest accuracy of 93.17% inferred by CIFAR-10. Within the RT, a maximum accuracy loss is 0.05%. In addition, the work maintains a CIFAR-100 accuracy of 68.23% to 68.12% at 4.2K, with a maximum accuracy loss of 0.11%.

As shown in FIG. 7, the present disclosure achieves a macro-module design of up to 144 Kb in a 40 nm CMOS process, which improves computational energy efficiency while maintaining a high computational density. The CIMC achieves an energy efficiency of 603 TOPS/W, which is 2.37 times higher than that achieved by most advanced 5 nm technology research [6]. The work can also achieve computational density of 284 TOPS/mm².

What is claimed is:

1. An energy-efficient cryogenic-in-memory-computing (CIMC) accelerator, comprising cryogenic 3T (C3T) macros, wherein each of the C3T macros comprises a C3T array containing M rows×N columns of bitcells, an input signal is converted into a timing sequence signal of a corresponding pulse width by using a digital timing sequence converter array, and a C3T bitcell of a corresponding row in the C3T macro is controlled to perform charging and discharging on a read bit line (RBL) of a corresponding column; and a voltage on the RBL of the corresponding column is sampled by a sense amplifier configured in each C3T macro to obtain a final result, wherein
during a non-convolutional operation, the RBL of the corresponding column is directly connected to the sense amplifier; and
in a convolutional operation mode, on or off of a switch is controlled, wherein: convolutional capacitors of a same size are connected to an RBL of each column; after the convolutional capacitors are charged and discharged, RBLs of adjacent two columns are connected together to achieve charge redistribution between different columns; and the RBL is disconnected from the sense amplifier, and charges of different magnitudes on different columns are sampled by the sense amplifier to generate a final output result.

2. The energy-efficient CIMC accelerator according to claim 1, wherein the C3T bitcell comprises a transmission gate write port constituted by a pair of complementary metal-oxide-semiconductor transistor (CMOS) structures and a read port constituted by a single-transistor N-channel metal oxide semiconductor (NMOS); for a write operation, stored data is written into a storage node (SN) through a write bit line (WBL) and the transmission gate write port controlled by a pair of a write word line (WWL) and a write word line bar (WWLB); and for a read operation, different charging and discharging behaviors of the RBL are achieved by controlling a pulse width length of a read signal read word line (RWL).

3. The energy-efficient CIMC accelerator according to claim 1, wherein each of two input terminals of the sense amplifier is provided with one transmission gate switch and one storage capacitor; a sampling transistor and the transmission gate switch of the input terminal on each side of the sense amplifier constitute an SN for storing a sampled voltage V_{REF}; in a sampling process, the voltage on the RBL is latched in the sampled voltage V_{REF} by the transmission gate switch on a first side of the sense amplifier; and after the sampled voltage is latched, the transmission gate switch on the first side of the sense amplifier is in a disconnected state to ensure that the sampled voltage is not affected by a voltage change on the RBL and is kept stored in the V_{REF}; and an actual computing result is sampled by the transmission gate switch on a second side of the sense amplifier and compared with the stored V_{REF} to generate the final output result.

4. The energy-efficient CIMC accelerator according to claim 3, wherein the sense amplifier is configured to impletement Boolean computing by following steps:
storing reference data of a corresponding sampled voltage into the C3T macro;
enabling a plurality of rows of word lines of the C3T macro to generate a corresponding column-oriented result;
connecting RBLs of adjacent columns to obtain a charge redistribution result; and
storing the charge redistribution result to the sense amplifier of a corresponding column, and latching the charge redistribution result in the V_{REF}, wherein for any input NAND or NOR operation, a reference voltage for determining the result is generated and stored to the sense amplifier to achieve a corresponding computing operation.

5. The energy-efficient CIMC accelerator according to claim 4, wherein a single 4-bit flash analog-to-digital converter (ADC) is formed by 15 sense amplifiers in the C3T macro, and adaptive 15 V_{REF} S are generated before the convolutional operation.
